(19) United States
(12) Patent Application Publication
(10) Pub. No.: US 2026/0344446 A1
(43) Pub. Date: Oct. 29, 2026

(54) INPUT/OUTPUT-SIDE COMPARTMENTAL SHIELDING FOR E-BAR PACKAGES AND APPLICATIONS THEREOF

(71) Applicant: Qorvo US, Inc., Greensboro, NC (US)

(72) Inventors: David Doerr, Plano, TX (US); Dennis Quaintance, Richardson, TX (US); Curtis Miller, Wylie, TX (US)

(21) Appl. No.: 19/550,051

(22) Filed: Feb. 25, 2026

Related U.S. Application Data
(60) Provisional application No. 63/794,046, filed on Apr. 24, 2025.

(51) Int. Cl. H10W 42/60; H10W 70/00; H10W 74/00; H10W 74/01; H10W 90/00

(52) U.S. Cl. CPC H10W 42/60; H10W 70/099; H10W 74/00; H10W 74/01; H10W 90/701

(57) ABSTRACT

Aspects of the disclosure provide a semiconductor package and a method for preparing the same. The semiconductor package includes a semiconductor die disposed on a substrate, an e-bar disposed proximate to the semiconductor die, and a plurality of wire bonds formed between the e-bar and a grounded portion of the substrate. In various embodiments, the wire bonds act as a Faraday cage that shields the semiconductor die from undesired electromagnetic interferences. In various embodiments, the e-bar includes a notch near a distal portion of the e-bar and the notch includes a bond pad for attaching the wire bonds. In various embodiments, the semiconductor package may include a mold compound that encapsulates portions of the semiconductor die, the e-bar, and the wire bonds, wherein the mold compound includes a co-grounded surface that exposes an electrical contact of the e-bar. In various embodiments, a wireless device includes the disclosed semiconductor package.

### CROSS-REFERENCE TO RELATED APPLICATION

This application claims priority to U.S. Patent Application No. 63/794,046, filed Apr. 24, 2025, all of which is incorporated by reference herein in its entirety.

### TECHNICAL FIELD

The present disclosure relates generally to semiconductor packaging methodologies, and in particular, relates to a semiconductor package and a method for preparing a semiconductor package with a system-in-package module having an input/output-side compartmental shielding for e-bar packages suitable for radio frequency (RF) applications.

### BACKGROUND

Advanced semiconductor electronics are typically assembled using cutting-edge packaging techniques. Advanced three-dimensional (3D) packaging technologies, for example, are suitable for use in preparing system-in-package type modules, such as those with multiple functional blocks that require minimal signal interference between the blocks. Such modules, including those implemented with e-bar packages are well established system-in-package concepts, typically using a laminate bar to transmit signal over a standoff. In some of the implementations, the e-bars are used either to extract heat from the side of the package that is normally used for signal input or output (I/O) or to make a double-sided package with the clearance for large components on the bottom side. If compartmental shielding is needed, it may be difficult on the I/O side of an e-bar package in such modules because it would require patterning metal on top of the mold compound such that the sputter-deposited material would not short the signal to ground. As such, an innovative solution is needed to address the challenges of integrating diverse semiconductor technologies in multiple functional blocks using e-bar packages while providing compartmental shielding that allows for isolation of electromagnetic signal interference between compartmentalized sections of a package generally suitable for use in next generation RF applications.

### SUMMARY

Embodiments of the present disclosure include advanced semiconductor packaging techniques with innovative packaging solutions designed for preparing a system-in-package module having an input/output-side compartmental shielding for e-bar packages. Aspects of the disclosure advantageously provide a semiconductor package and one or more methods for preparing a semiconductor package with compartmental shielding for e-bar packages suitable for radio frequency (RF) applications.

In an exemplary aspect, a semiconductor package is provided. The semiconductor package includes a semiconductor die disposed on a substrate; an e-bar disposed proximate to the semiconductor die on the substrate; and a plurality of wire bonds formed between the e-bar and a grounded portion of the substrate, wherein the plurality of wire bonds act as a Faraday cage that shields the semiconductor die from undesired electromagnetic interferences.

In one or more embodiments, the e-bar may include a notch near a distal portion of the e-bar and wherein a proximal portion of the e-bar is attached to the substrate. In one or more embodiments, the notch of the e-bar may include a bond pad for attaching the plurality of wire bonds.

In one or more embodiments, the semiconductor package may include a mold compound that encapsulates at least portions of the semiconductor die, the e-bar, and the plurality of wire bonds, wherein the mold compound comprises a co-grounded surface that exposes an electrical contact of the e-bar.

In one or more embodiments, the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, and the semiconductor package may further include a second semiconductor die disposed at a second location of the substrate; a second e-bar disposed proximate to the second semiconductor die on the substrate; and a second plurality of wire bonds formed between the second e-bar and a second grounded portion of the substrate, wherein the second plurality of wire bonds act as a second Faraday cage that shields the second semiconductor die from undesired electromagnetic interferences. In one or more embodiments, the second e-bar may include a second notch near a distal portion of the second e-bar and wherein a proximal portion of the second e-bar is attached to the substrate. In one or more embodiments, the second notch of the second e-bar may include a bond pad for attaching the second plurality of wire bonds.

In one or more embodiments, the first semiconductor die may include a wire bond die and the second semiconductor die may include a flip chip die, the first semiconductor die may include a flip chip die and the second semiconductor die may include a wire bond die, the first semiconductor die and the second semiconductor die both include a flip chip die, or the first semiconductor die and the second semiconductor die both include a wire bond die.

In one or more embodiments, a wireless device may include the semiconductor package as disclosed herein.

In an exemplary aspect, a method for preparing a semiconductor package is provided. The method includes disposing a semiconductor die on a substrate; disposing an e-bar proximate to the semiconductor die on the substrate; and forming a plurality of wire bonds between the e-bar and a grounded portion of the substrate, wherein the plurality of wire bonds act as a Faraday cage that shields the semiconductor die from undesired electromagnetic interferences.

In one or more embodiments of the method, the e-bar may include a notch near a distal portion of the e-bar and wherein a proximal portion of the e-bar is attached to the substrate. In one or more embodiments, the notch of the e-bar may include a bond pad and wherein forming the plurality of wire bonds may include forming the plurality of wire bonds between the bond pad of the notch of the e-bar and the grounded portion of the substrate.

In one or more embodiments, the method may also include forming a mold compound that encapsulates at least portions of the semiconductor die, the e-bar, and the plurality of wire bond; and co-grinding the mold compound to form a co-grounded surface that exposes an electrical contact of the e-bar.

In one or more embodiments of the method, the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, the method may further include disposing a second semiconductor die at a second location of the substrate; disposing a second e-bar proximate to the second semiconductor die on the substrate; and forming a second plurality of wire bonds between the second e-bar and a second grounded portion of the substrate, wherein the second plurality of wire bonds act as a second Faraday cage that shields the second semiconductor die from undesired electromagnetic interferences.

In one or more embodiments of the method, the second e-bar may include a second notch near a distal portion of the second e-bar, wherein a proximal portion of the second e-bar is attached to the substrate, and wherein the second notch of the second e-bar may include a bond pad for attaching the second plurality of wire bonds.

In one or more embodiments of the method, the first semiconductor die may include a wire bond die and the second semiconductor die may include a flip chip die, the first semiconductor die may include a flip chip die and the second semiconductor die may include a wire bond die, the first semiconductor die and the second semiconductor die both include a flip chip die, or the first semiconductor die and the second semiconductor die both include a wire bond die.

In one or more embodiments, a wireless device may include the semiconductor package produced using the method described herein.

In an exemplary aspect, a wireless device is provided. The wireless device includes a semiconductor package that includes a semiconductor die disposed on a substrate, an e-bar disposed proximate to the semiconductor die on the substrate, and a plurality of wire bonds formed between the e-bar and a grounded portion of the substrate, wherein the plurality of wire bonds act as a Faraday cage that shields the semiconductor die from undesired electromagnetic interferences.

In one or more embodiments of the wireless device, the e-bar may include a notch near a distal portion of the e-bar, wherein a proximal portion of the e-bar is attached to the substrate, and wherein the notch of the e-bar may include a bond pad for attaching the plurality of wire bonds.

In one or more embodiments of the wireless device, the semiconductor package may further include a mold compound that encapsulates at least portions of the semiconductor die, the e-bar, and the plurality of wire bonds, wherein the mold compound comprises a co-grounded surface that exposes an electrical contact of the e-bar.

In one or more embodiments of the wireless device, the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, wherein the semiconductor package may further include a second semiconductor die disposed at a second location of the substrate; a second e-bar disposed proximate to the second semiconductor die on the substrate; and a second plurality of wire bonds formed between the second e-bar and a second grounded portion of the substrate, wherein the second plurality of wire bonds act as a second Faraday cage that shields the second semiconductor die from undesired electromagnetic interferences.

In one or more embodiments of the wireless device, the first semiconductor die may include a wire bond die and the second semiconductor die may include a flip chip die, the first semiconductor die may include a flip chip die and the second semiconductor die may include a wire bond die, the first semiconductor die and the second semiconductor die both include a flip chip die, or the first semiconductor die and the second semiconductor die both include a wire bond die.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIGS. 1A, 1B, and 1C illustrate various examples of a semiconductor package, according to aspects of the present disclosure.

FIG. 2 illustrates a flowchart for a method for preparing an example semiconductor package, according to aspects of the present disclosure.

FIG. 3 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include advanced semiconductor manufacturing methodologies for preparing a semiconductor package with a system-in-package module having an input/output-side compartmental shielding for e-bar packages suitable for radio frequency (RF) applications. The disclosed semiconductor package may include multiple RF dies using mixed technologies within the system-in-package module. The disclosed semiconductor manufacturing process may include, among many others, utilizing a combination of e-bars and wire bonds connected between e-bars and grounded portions of the substrate to form Faraday cages to shield electromagnetic interferences between the dies. One or more e-bars included in the package include notches or lips that can include bond pads for attaching one end of the wire bonds. The package may be over-molded with a mold compound and co-grinded to reveal electrical connects of the e-bars for input/output connections. Thus, the disclosed embodiments of the advanced semiconductor manufacturing methodologies illustrate a semiconductor package having one or more dies, including for example but not limited to gallium nitride (GaN) and gallium arsenide (GaAs) dies, and a method for preparing a semiconductor package with a system-in-package module having an input/output-side compartmental shielding using e-bar packages.

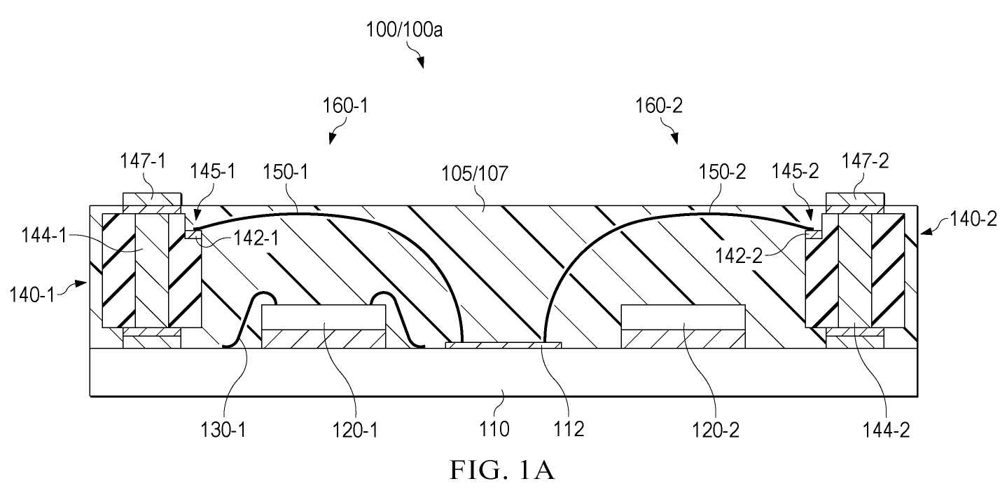

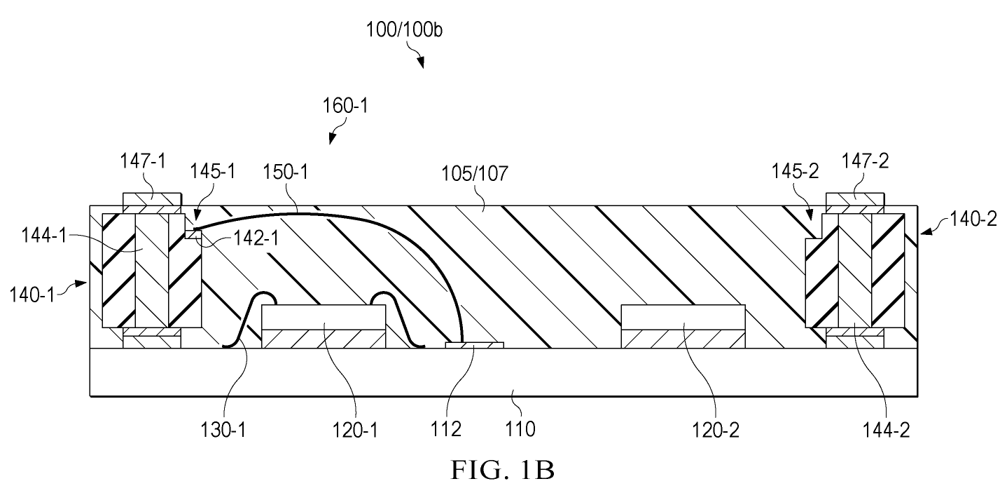

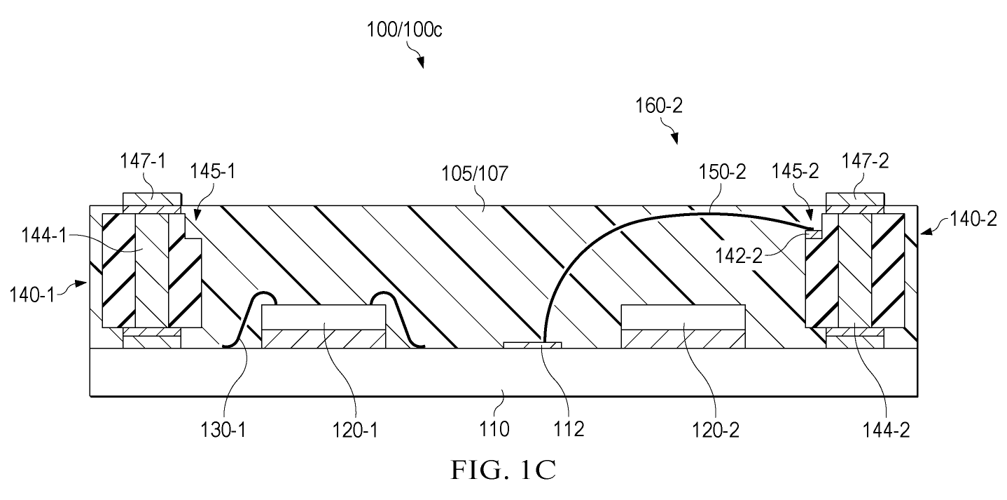

Various embodiments disclosed herein provide a semiconductor package having an input/output-side compartmental shielding using e-bars and a method for preparing the same, the disclosures of which are described in further detail with respect to the FIGS. 1A, 1B, 1C, 2 and 3.

FIGS. 1A, 1B, and 1C illustrate various examples of a semiconductor package 100, according to aspects of the present disclosure. Specifically, FIG. 1A illustrates an embodiment of the semiconductor package 100, namely, semiconductor package 100a having multiple shielded dies, FIG. 1B illustrates another embodiment of the semiconductor package 100, namely, semiconductor package 100b having a shielded wire bond die, and FIG. 1C illustrates yet another embodiment of the semiconductor package 100, namely, semiconductor package 100c having a shielded flip chip die, according to aspects of the present disclosure. In other words, the semiconductor package 100 may include at least one shielded die, as in semiconductor package 100b or semiconductor package 100c, or multiple shielded dies, as in semiconductor package 100a.

In one or more embodiments, the semiconductor package 100, namely, semiconductor packages 100a, 100b, and 100c each may include a wide band gap semiconductor package having an input/output-side compartmental shielding using e-bars. In some embodiments, the semiconductor package 100, namely, semiconductor packages 100a, 100b, and 100c each may be produced or manufactured using advanced semiconductor packaging techniques as disclosed herein. In one or more embodiments, a wireless device may include the semiconductor package 100, namely, semiconductor packages 100a, 100b, and 100c, as disclosed herein.

FIG. 1A depicts a cross-sectional view of the semiconductor package 100a, which includes multiple individually shielded dies 120-1 and 120-2. Similarly, FIG. 1B illustrates a cross-sectional view of the semiconductor package 100b, which includes a shielded wire bond die 120-1 and an unshielded flip chip die 120-2. FIG. 1C illustrates a cross-sectional view of the semiconductor package 100c, which includes an unshielded wire bond die 120-1 and a shielded flip chip die 120-2. As depicted in the figures, the semiconductor die 120-1 (also referred to herein as “first semiconductor die”) and semiconductor die 120-2 (also referred to herein as “second semiconductor die”) are disposed on a substrate 110. In various embodiments, the semiconductor die 120-1 may be disposed at a first location (e.g., left side of the figures) of the substrate 110 and the semiconductor die 120-2 may be disposed at a second location (e.g., right side of the figures) of the substrate 110, as illustrated in FIGS. 1A, 1B, and 1C. Although semiconductor die 120-1 and semiconductor die 120-2 are illustrated in FIGS. 1A, 1B, and 1C as a wire bond die and a flip chip die, respectively, either or both of semiconductor die 120-1 and semiconductor die 120-2 may include any type of dies, including wire bond dies and flip chip dies, in various embodiments.

As shown in FIGS. 1A, 1B, and 1C,either or both semiconductor dies 120-1 or 120-2 may be shielded. For example, the semiconductor package 100b includes a shielded wire bond die 120-1 and an unshielded flip chip die 120-2, as illustrated in FIG. 1B and the semiconductor package 100c includes unshielded wire bond die 120-1 and a shielded flip chip die 120-2, as illustrated in FIG. 1C. As illustrated in FIGS. 1A, 1B, and 1C, the semiconductor die 120-1 is a wire bond die and further includes wire bonds 130-1.

As shown in FIG. 1A, the semiconductor package 100a includes an e-bar, such as e-bar 140-1 (also referred to herein as “first e-bar”) or e-bar 140-2 (also referred to herein as “first e-bar”), disposed proximate to the semiconductor die, such as semiconductor die 120-1 or semiconductor die 120-2, on the substrate 110. In various embodiments, e-bar 140-1 is disposed proximate to the semiconductor die 120-1 on the substrate 110 and e-bar 140-2 is disposed proximate to the semiconductor die 120-2 on the substrate 110. In some embodiments, e-bar 140-1 is disposed proximate to the semiconductor die 120-1 on the substrate 110. In some embodiments, e-bar 140-2 is disposed proximate to the semiconductor die 120-2 on the substrate 110.

As further illustrated in FIG. 1A, the semiconductor package 100a includes a plurality of wire bonds, such as wire bonds 150-1 (also referred to herein as “first plurality of wire bonds”) and/or wire bonds 150-2 (also referred to herein as “second plurality of wire bonds”), that are formed between the e-bar, such as e-bar 140-1 or e-bar 140-2, and a grounded portion 112 of the substrate 110, wherein the plurality of wire bonds, such as wire bonds 150-1 and/or wire bonds 150-2, act as a Faraday cage, such as Faraday cage 160-1 (also referred to herein as “first Faraday cage”) and/or Faraday cage 160-2 (also referred to herein as “first Faraday cage”), that shields the semiconductor die, such as semiconductor die 120-1 and/or semiconductor die 120-2, from undesired electromagnetic interferences (not shown). In various embodiments, wire bonds 150-1 act as Faraday cage 160-1 that shields the semiconductor die 120-1 from undesired electromagnetic interferences and wire bonds 150-2 act as Faraday cage 160-2 that shields the semiconductor die 120-2 from undesired electromagnetic interferences. In some embodiments, wire bonds 150-1 act as Faraday cage 160-1 that shields the semiconductor die 120-1 from undesired electromagnetic interferences. In some embodiments, wire bonds 150-2 act as Faraday cage 160-2 that shields the semiconductor die 120-2 from undesired electromagnetic interferences. In other words, wire bonds 150-1 and wire bonds 150-2 form a bird’s nest of wires that are grounded and placed above the area (e.g., dies 120-1 or 120-2) of the semiconductor package 100 that needs to be compartmentally shielded. Said another way, such “nest” of bond wires compartmentally shields the area of the semiconductor package 100 it is built over.

FIG. 1A also illustrates that the e-bar, such as e-bar 140-1 or e-bar 140-2, includes a notch, such as notch 145-1 or notch 145-2, near a distal portion (top) of the e-bar and wherein a proximal portion (bottom) of the e-bar is attached to the substrate 110. In other words, e-bar 140-1 includes a notch 145-1 near a distal portion (top) of the e-bar 140-1, wherein a proximal portion (bottom) of the e-bar 140-1 is attached to the substrate 110 and e-bar 140-2 includes a notch 145-2 near a distal portion (top) of the e-bar 140-2, wherein a proximal portion (bottom) of the e-bar 140-2 is attached to the substrate 110, in various embodiments. In some embodiments, e-bar 140-1 includes a notch 145-1 near a distal portion (top) of the e-bar 140-1, wherein a proximal portion (bottom) of the e-bar 140-1 is attached to the substrate 110. In some embodiments, e-bar 140-2 includes a notch 145-2 near a distal portion (top) of the e-bar 140-2, wherein a proximal portion (bottom) of the e-bar 140-2 is attached to the substrate 110.

In various embodiments, the notch, such as notch 145-1 or notch 145-2 of the e-bar, such as e-bar 140-1 or e-bar 140-2, includes a bond pad, such as bond pad 142-1 or bond pad 142-2, for attaching the plurality of wire bonds, such as wire bonds 150-1 or wire bonds 150-2. In various embodiments, notch 145-1 of the e-bar 140-1 includes a bond pad 142-1 for attaching the wire bonds 150-1 and notch 145-2 of the e-bar 140-2 includes a bond pad 142-2 for attaching the wire bonds 150-2. In some embodiments, notch 145-1 of the e-bar 140-1 includes a bond pad 142-1 for attaching the wire bonds 150-1. In some embodiments, notch 145-2 of the e-bar 140-2 includes a bond pad 142-2 for attaching the wire bonds 150-2.

In various embodiments, the e-bar, such as e-bar 140-1 or e-bar 140-2, includes a thick organic laminate, which may include a material, such as but not limited to a fire-retardant material, e.g., FR-4. In various embodiments, the e-bar may include a via, such as via 144-1 or via 144-2, that is connected to an electrical contact, such as electrical contact 147-1 and/or electrical contact 147-2, as shown in FIGS. 1A, 1B, and 1C. The electrical contact, such as electrical contact 147-1 and/or electrical contact 147-2 can provide a signal transmission through the via, such as vias 144-1 and 144-2, of the e-bar, such as e-bar 140-1 or e-bar 140-2, respectively.

As further illustrated in FIGS. 1A, 1B, and 1C the e-bars 140-1 and e-bar 140-2 are disposed on the substrate 110 and are molded via a mold compound 105 such that the electrical contacts 147-1 and 147-2 of the e-bars 140-1 and 140-2 are exposed. In other words, the semiconductor package 100, namely, semiconductor packages 100a, 100b, and 100c each includes a mold compound 105 that encapsulates at least portions of the semiconductor die, such as semiconductor die 120-1 and/or semiconductor die 120-2, the e-bar, such as e-bar 140-1 and/or e-bar 140-2, and the plurality of wire bonds, such as wire bonds 150-1 or wire bonds 150-2. Furthermore, the mold compound 105 includes a co-grounded surface 107 that exposes the electrical contact, such as electrical contact 147-1 and/or electrical contact 147-2 of the e-bar. In one or more embodiments, a selective molding, such as but not limited to, a film-assisted molding technique, can be used to form the mold compound 105 with a surface, such as the surface 107, that exposes the electrical contact, such as electrical contact 147-1 and/or electrical contact 147-2 of the e-bar. In other words, surface 107 may be formed via co-grounding or via a selective molding process. In various embodiments, the mold compound 105 encapsulates at least portions of the semiconductor die 120-1, the e-bar 140-1, and the plurality of wire bonds 150-1, wherein the co-grounded surface 107 (or selectively molded surface 107) exposes electrical contact 147-1 of the e-bar 140-1 and at least portions of the semiconductor die 120-2, the e-bar 140-2, and the plurality of wire bonds 150-2, wherein the co-grounded surface 107 exposes electrical contact 147-2 of the e-bar 140-2. In some embodiments, the mold compound 105 encapsulates at least portions of the semiconductor die 120-1, the e-bar 140-1, and the plurality of wire bonds 150-1, wherein the co-grounded surface 107 exposes electrical contact 147-1 of the e-bar 140-1. In some embodiments, the mold compound 105 encapsulates at least portions of the semiconductor die 120-2, the e-bar 140-2, and the plurality of wire bonds 150-2, wherein the co-grounded surface 107 exposes electrical contact 147-2 of the e-bar 140-2.

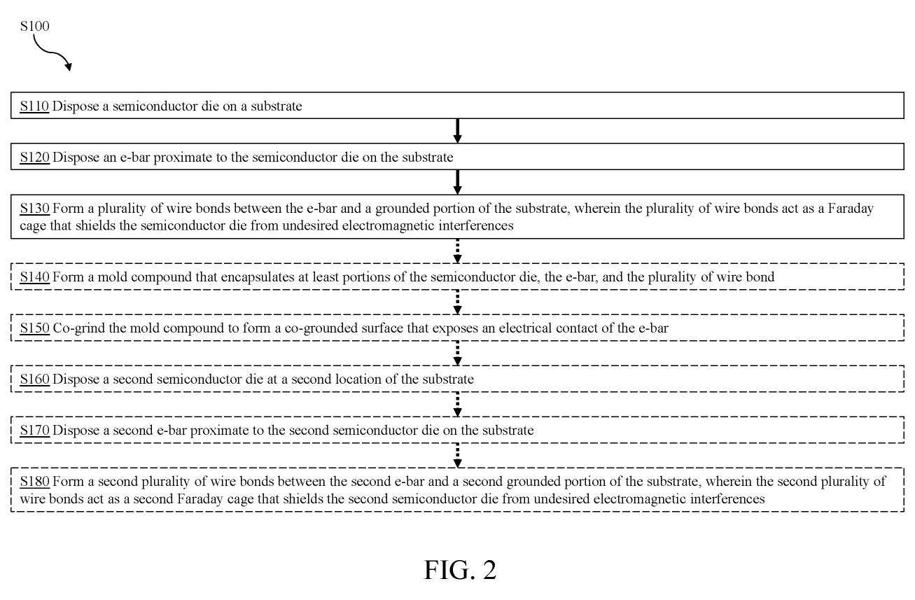

FIG. 2 illustrates a flowchart for a method S100 for preparing a semiconductor package, according to aspects of the present disclosure. In one or more embodiments, the semiconductor package produced via the method S100 may include a semiconductor package, such as the semiconductor package 100, namely, semiconductor packages 100a, 100b, and 100c, as described with respect to FIGS. 1A, 1B, and 1C.

As shown in FIG. 2, the method S100 includes, at step S110, disposing a semiconductor die on a substrate. In one or more embodiments, the semiconductor die includes a semiconductor die, such as the semiconductor dies 120-1 or 120-2, the substrate includes a substrate, such as the substrate 110, as described with respect to FIGS. 1A, 1B, AND 1C.

The method S100 further includes, at step S120, disposing an e-bar proximate to the semiconductor die on the substrate. In one or more embodiments, the e-bar includes an e-bar, such as the e-bar 140-1 and 140-2, as described with respect to FIGS. 1A, 1B, and 1C.

The method S100 further includes, at step S130, forming a plurality of wire bonds between the e-bar and a grounded portion of the substrate, wherein the plurality of wire bonds act as a Faraday cage that shields the semiconductor die from undesired electromagnetic interferences. In one or more embodiments, the plurality of wire bonds includes a plurality of wire bonds, such as the plurality of wire bonds 150-1 or 150-2, the Faraday cage includes a Faraday cage, such as the Faraday cage 160-1 and Faraday cage 160-2, as described with respect to FIGS. 1A, 1B, and 1C.

In one or more embodiments of the method S100, the e-bar may include a notch near a distal portion of the e-bar and wherein a proximal portion of the e-bar is attached to the substrate. In one or more embodiments, the notch of the e-bar may include a bond pad and wherein forming the plurality of wire bonds may include forming the plurality of wire bonds between the bond pad of the notch of the e-bar and the grounded portion of the substrate. In one or more embodiments, the notch includes a notch, such as notch 145-1 and 145-2, the bond pad includes a bond pad, such as bond pad 142-1 and bond pad 142-2, as described with respect to FIGS. 1A, 1B, and 1C.

In one or more embodiments, the method S100 may further include, optionally at step S140, forming a mold compound that encapsulates at least portions of the semiconductor die, the e-bar, and the plurality of wire bond; and optionally at step S150, co-grinding the mold compound to form a co-grounded surface that exposes an electrical contact of the e-bar. In one or more embodiments, the mold compound includes a mold compound, such as mold compound 105, the co-grounded surface includes a co-grounded surface, such as co-grounded surface 107, as described with respect to FIGS. 1A, 1B, and 1C. In one or more embodiments, the step S140 may include applying a selective molding to produce a mold compound with a selectively molded surface, such as surface 107, that exposes an electrical contact of the e-bar.

In one or more embodiments of the method S100, the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, and the method S100 may further include, optionally at step S160, disposing a second semiconductor die at a second location of the substrate; optionally at step S170, disposing a second e-bar proximate to the second semiconductor die on the substrate; and optionally at step S180, forming a second plurality of wire bonds between the second e-bar and a second grounded portion of the substrate, wherein the second plurality of wire bonds act as a second Faraday cage that shields the second semiconductor die from undesired electromagnetic interferences. In one or more embodiments, the first semiconductor die includes semiconductor die 120-1, the second semiconductor die includes semiconductor die 120-2, the first e-bar includes e-bar 140-1, the second e-bar includes e-bar 140-2, the first plurality of wire bonds include wire bonds 150-1, the second plurality of wire bonds include wire bonds 150-2, as described with respect to FIGS. 1A, 1B, and 1C.

In one or more embodiments of the method S100, the second e-bar may include a second notch near a distal portion of the second e-bar, wherein a proximal portion of the second e-bar is attached to the substrate, and wherein the second notch of the second e-bar may include a bond pad for attaching the second plurality of wire bonds.

In one or more embodiments of the method S100, the first semiconductor die may include a wire bond die and the second semiconductor die may include a flip chip die, the first semiconductor die may include a flip chip die and the second semiconductor die may include a wire bond die, the first semiconductor die and the second semiconductor die both include a flip chip die, and/or the first semiconductor die and the second semiconductor die both include a wire bond die.

In one or more embodiments of the method S100, the first semiconductor die may include a wire bond die and the second semiconductor die may include a flip chip die. In one or more embodiments, the first semiconductor die may include a flip chip die and the second semiconductor die may include a wire bond die. In one or more embodiments, the first semiconductor die and the second semiconductor die both include a flip chip die. In one or more embodiments, the first semiconductor die and the second semiconductor die both include a wire bond die.

In one or more embodiments, a wireless device may include the semiconductor package produced using the method S100 described herein.

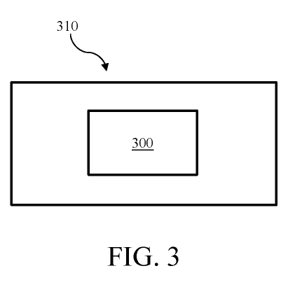

FIG. 3 illustrates an electronic device or a wireless device 310 comprising a semiconductor package 300, according to aspects of the present disclosure. In some implementations, the electronic device or wireless device 310 may include, for example, but not limited to, a computer, a cellular device, a satellite communication device, a wi-fi device, a radar, a global position system device, or any electronic device. In one or more embodiments, the semiconductor package 300 may be produced in accordance with the method S100 described with respect to FIG. 2, and/or may include a semiconductor package, such as the semiconductor package 100, namely semiconductor packages 100a, 100b, and 100c, as described with respect to FIGS. 1A, 1B, and 1C. The semiconductor package may implement any RF circuitry used in wireless applications, as an example, such as one or more RF power amplifiers; and the semiconductor package may be coupled to other circuitry for implementing a wireless application, such as a baseband processor or other types of processors.

In one or more embodiments, the wireless device 310 may include the semiconductor package 300. In one or more embodiments, the semiconductor package 300 includes a semiconductor die disposed on a substrate, an e-bar disposed proximate to the semiconductor die on the substrate, and a plurality of wire bonds formed between the e-bar and a grounded portion of the substrate, wherein the plurality of wire bonds act as a Faraday cage that shields the semiconductor die from undesired electromagnetic interferences. In one or more embodiments, the semiconductor die includes a semiconductor die, such as the semiconductor dies 120-1 or 120-2, the substrate includes a substrate, such as the substrate 110, the e-bar includes an e-bar, such as the e-bar 140-1 and 140-2, the plurality of wire bonds includes a plurality of wire bonds, such as the plurality of wire bonds 150-1 or 150-2, and the Faraday cage includes a Faraday cage, such as the Faraday cage 160-1 and Faraday cage 160-2, as described with respect to FIGS. 1A, 1B, and 1C

In one or more embodiments of the wireless device 310, the e-bar may include a notch near a distal portion of the e-bar, wherein a proximal portion of the e-bar is attached to the substrate, and wherein the notch of the e-bar may include a bond pad for attaching the plurality of wire bonds. In one or more embodiments, the notch includes a notch, such as notch 145-1 and 145-2, the bond pad includes a bond pad, such as bond pad 142-1 and bond pad 142-2, as described with respect to FIGS. 1A, 1B, and 1C.

In one or more embodiments of the wireless device 310, the semiconductor package 300 may further include a mold compound that encapsulates at least portions of the semiconductor die, the e-bar, and the plurality of wire bonds, wherein the mold compound comprises a co-grounded surface that exposes an electrical contact of the e-bar. In one or more embodiments, the mold compound includes a mold compound, such as mold compound 105, the co-grounded surface includes a co-grounded surface, such as co-grounded surface 107, as described with respect to FIGS. 1A, 1B, 1C. In one or more embodiments, a selective molding, such as but not limited to, a film-assisted molding technique, can be used to form a mold compound, such as the mold compound 105 with a surface, such as the surface 107, that exposes the electrical contacts, such as electrical contact 147-1 and/or electrical contact 147-2 of the e-bar.

In one or more embodiments of the wireless device 310, the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, wherein the semiconductor package may further include a second semiconductor die disposed at a second location of the substrate; a second e-bar disposed proximate to the second semiconductor die on the substrate; and a second plurality of wire bonds formed between the second e-bar and a second grounded portion of the substrate, wherein the second plurality of wire bonds act as a second Faraday cage that shields the second semiconductor die from undesired electromagnetic interferences. In one or more embodiments, the first semiconductor die includes semiconductor die 120-1, the second semiconductor die includes semiconductor die 120-2, the first e-bar includes e-bar 140-1, the second e-bar includes e-bar 140-2, the first plurality of wire bonds include wire bonds 150-1, the second plurality of wire bonds include wire bonds 150-2, as described with respect to FIGS. 1A, 1B, and 1C.

In one or more embodiments of the wireless device 310, the first semiconductor die may include a wire bond die and the second semiconductor die may include a flip chip die, the first semiconductor die may include a flip chip die and the second semiconductor die may include a wire bond die, the first semiconductor die and the second semiconductor die both include a flip chip die, and/or the first semiconductor die and the second semiconductor die both include a wire bond die.

In one or more embodiments of the wireless device 310, the first semiconductor die may include a wire bond die and the second semiconductor die may include a flip chip die. In one or more embodiments, the first semiconductor die may include a flip chip die and the second semiconductor die may include a wire bond die. In one or more embodiments, the first semiconductor die and the second semiconductor die both include a flip chip die. In one or more embodiments, the first semiconductor die and the second semiconductor die both include a wire bond die.

In one or more embodiments, the semiconductor package 300 of the wireless device 310 may be produced via the method S100, as described with respect to FIG. 2.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package, comprising:
a semiconductor die disposed on a substrate;
an e-bar disposed proximate to the semiconductor die on the substrate; and
a plurality of wire bonds formed between the e-bar and a grounded portion of the substrate, wherein the plurality of wire bonds act as a Faraday cage that shields the semiconductor die from undesired electromagnetic interferences.

2. The semiconductor package of claim 1, wherein the e-bar comprises a notch near a distal portion of the e-bar and wherein a proximal portion of the e-bar is attached to the substrate.

3. The semiconductor package of claim 2, wherein the notch of the e-bar comprises a bond pad for attaching the plurality of wire bonds.

4. The semiconductor package of claim 1, further comprising:
a mold compound that encapsulates at least portions of the semiconductor die, the e-bar, and the plurality of wire bonds, wherein the mold compound comprises a co-grounded surface that exposes an electrical contact of the e-bar.

5. The semiconductor package of claim 1, wherein the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, further comprising:
a second semiconductor die disposed at a second location of the substrate;
a second e-bar disposed proximate to the second semiconductor die on the substrate; and
a second plurality of wire bonds formed between the second e-bar and a second grounded portion of the substrate, wherein the second plurality of wire bonds act as a second Faraday cage that shields the second semiconductor die from undesired electromagnetic interferences.

6. The semiconductor package of claim 5, wherein the second e-bar comprises a second notch near a distal portion of the second e-bar and wherein a proximal portion of the second e-bar is attached to the substrate.

7. The semiconductor package of claim 6, wherein the second notch of the second e-bar comprises a bond pad for attaching the second plurality of wire bonds.

8. The semiconductor package of claim 5, wherein:
the first semiconductor die comprises a wire bond die and the second semiconductor die comprises a flip chip die,
the first semiconductor die comprises a flip chip die and the second semiconductor die comprises a wire bond die,
the first semiconductor die and the second semiconductor die both comprise a flip chip die, or
the first semiconductor die and the second semiconductor die both comprise a wire bond die.

9. A method for preparing a semiconductor package, comprising:
disposing a semiconductor die on a substrate;
disposing an e-bar proximate to the semiconductor die on the substrate; and
forming a plurality of wire bonds between the e-bar and a grounded portion of the substrate, wherein the plurality of wire bonds act as a Faraday cage that shields the semiconductor die from undesired electromagnetic interferences.

10. The method of claim 9, wherein the e-bar comprises a notch near a distal portion of the e-bar and wherein a proximal portion of the e-bar is attached to the substrate.

11. The method of claim 10, wherein the notch of the e-bar comprises a bond pad and wherein forming the plurality of wire bonds comprises forming the plurality of wire bonds between the bond pad of the notch of the e-bar and the grounded portion of the substrate.

12. The method of claim 9, further comprising:
forming a mold compound that encapsulates at least portions of the semiconductor die, the e-bar, and the plurality of wire bond; and
co-grinding the mold compound to form a co-grounded surface that exposes an electrical contact of the e-bar.

13. The method of claim 9, wherein the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, the method further comprises:
disposing a second semiconductor die at a second location of the substrate;
disposing a second e-bar proximate to the second semiconductor die on the substrate; and
forming a second plurality of wire bonds between the second e-bar and a second grounded portion of the substrate, wherein the second plurality of wire bonds act as a second Faraday cage that shields the second semiconductor die from undesired electromagnetic interferences.

14. The method of claim 13, wherein the second e-bar comprises a second notch near a distal portion of the second e-bar, wherein a proximal portion of the second e-bar is attached to the substrate, and wherein the second notch of the second e-bar comprises a bond pad for attaching the second plurality of wire bonds.

15. The method of claim 13, wherein:
the first semiconductor die comprises a wire bond die and the second semiconductor die comprises a flip chip die,
the first semiconductor die comprises a flip chip die and the second semiconductor die comprises a wire bond die,
the first semiconductor die and the second semiconductor die both comprise a flip chip die, or
the first semiconductor die and the second semiconductor die both comprise a wire bond die.

16. A wireless device, comprising:
a semiconductor package comprising a semiconductor die disposed on a substrate, an e-bar disposed proximate to the semiconductor die on the substrate, and a plurality of wire bonds formed between the e-bar and a grounded portion of the substrate,
wherein the plurality of wire bonds act as a Faraday cage that shields the semiconductor die from undesired electromagnetic interferences.

17. The wireless device of claim 16, wherein the e-bar comprises a notch near a distal portion of the e-bar, wherein a proximal portion of the e-bar is attached to the substrate, and wherein the notch of the e-bar comprises a bond pad for attaching the plurality of wire bonds.

18. The wireless device of claim 16, wherein the semiconductor package further comprises:
a mold compound that encapsulates at least portions of the semiconductor die, the e-bar, and the plurality of wire bonds, wherein the mold compound comprises a co-grounded surface that exposes an electrical contact of the e-bar.

19. The wireless device of claim 16, wherein the semiconductor die is a first semiconductor die disposed at a first location on the substrate, the e-bar is a first e-bar, the plurality of wire bonds are a first plurality of wire bonds, the grounded portion is a first grounded portion of the substrate, the Faraday cage is a first Faraday cage, wherein the semiconductor package further comprises:
a second semiconductor die disposed at a second location of the substrate;
a second e-bar disposed proximate to the second semiconductor die on the substrate; and
a second plurality of wire bonds formed between the second e-bar and a second grounded portion of the substrate, wherein the second plurality of wire bonds act as a second Faraday cage that shields the second semiconductor die from undesired electromagnetic interferences.

20. The wireless device of claim 19, wherein:
the first semiconductor die comprises a wire bond die and the second semiconductor die comprises a flip chip die,
the first semiconductor die comprises a flip chip die and the second semiconductor die comprises a wire bond die,
the first semiconductor die and the second semiconductor die both comprise a flip chip die, or
the first semiconductor die and the second semiconductor die both comprise a wire bond die.
